(19) United States
(12) Patent Application Publication
(10) Pub. No.: US 2005/0116344 A1
(43) Pub. Date: Jun. 2, 2005

(54) Microelectronic element having trace formed after bond layer

(75) Inventor: Giles Humpston, San Jose, CA (US)

Correspondence Address: LERNER DAVID, LITENBERG, KRUMHOLZ & MENTLIK, 600 SOUTH AVENUE WEST, WESTFIELD, NJ, 07090, US

(73) Assignee: Tessera, Inc., San Jose, CA (US)

(21) Appl. No.: 10/977,515

(22) Filed: Oct. 29, 2004

Related U.S. Application Data
(60) Provisional application No. 60/532,341, filed on Dec. 23, 2003.
(60) Provisional application No. 60/515,615, filed on Oct. 29, 2003.

(51) Int. Cl. H01L 23/48

(52) U.S. Cl. 257/750; 257/779; 257/753

(57) ABSTRACT

An article is provided which includes a structure overlying a face of an element. The structure includes a first metal layer and a wettable metal layer overlying the first metal layer. A conductive trace overlies and contacts at least one of the first metal layer and the wettable metal layer, the trace having a composition different from at least one of the first metal layer and the wettable metal layer.

### CROSS-REFERENCE TO RELATED APPLICATIONS

This application claims the benefit of the filing dates of U.S. Provisional Patent Application Nos. 60/515,615 filed Oct. 29, 2003 and 60/532,341 filed Dec. 23, 2003, the disclosures of which are hereby incorporated herein by reference.

### BACKGROUND OF THE INVENTION

The present invention relates to the packaging of electronic devices, especially microelectronic devices, and the manufacture of microelectronics devices and assemblies including microelectronic devices.

Many types of microelectronic and other miniature devices can be fabricated on semiconductor substrates, most commonly being semiconductor wafers. Such devices include integrated circuits, integrated passive devices such as “integrated passives on chips” (IPOCs), optoelectronic devices and micro-electromechanical systems (MEMs). Such electronic devices typically must be mounted to an interconnection element in a chip package before being mounted to a higher level assembly such as a circuit panel, e.g., a circuit board, card, or flexible circuit panel. Alternatively, through use of some techniques, e.g., wire-bonding, semiconductor chips can sometimes be mounted directly to a circuit panel. In another alternative, chips can be surface mounted to specially adapted circuit panels, i.e., those having thermal characteristics or flexibility that do not create excessive stresses on the chip.

Bonding techniques such as flip-chip attach methods which include attachment to ball grid arrays (BGA) or land grid arrays (LGA) formed on the semiconductor chip, offer several advantages for packaging microelectronic devices such as semiconductor chips. Such techniques are amenable to forming large numbers of conductive interconnects, at close spacings, between the chip and the interconnection element. Such techniques involve the simultaneous formation of fusible features, for example, solder bumps, over an array of bond pads of the chip or, alternatively, on a corresponding array of contacts of the interconnection element. After the fusible features are formed, the chip and the interconnection element are aligned and heated to a temperature which causes the fusible material of the features to melt and flow. At such time, features of the chip and of the interconnection element adjacent to the molten fusible material melt, dissolve, or diffuse into the fusible material to form a bond therewith.

It is evident that protection must be provided in these processes against the closely spaced fusible features flowing into and fusing to each other. It is also evident that protection must be provided during the bonding process against the molten fusible material flowing onto areas of the chip where it might cause damage. For example, wiring such as traces exposed at the front surface of the chip may be formed of a metal which melts or dissolves on contact with a molten fusible material such as solder. To avoid damage, the final bonding process must preclude the fusible material from contacting the wiring traces of the chip. In addition, the process by which the fusible material is applied to the chip prior to the final bonding must preclude the fusible material from contacting areas other than the bond pads.

In light of the above-stated concerns, it is common to apply a dielectric “passivation” layer to cover the wiring traces of the chip prior to performing steps which lead to the formation of a bondable layer on the chip and before forming features of fusible material in conductive communication with the bond pads.

Wire-bonding is another bonding technique which involves contacting a ball of metal to a bond pad of the chip. Wire-bonding must also avoid the ball contacting the wiring traces of the chip owing to metallurgical incompatibility between them. However, wire bonds that directly contact aluminum, copper or gold traces bond pads can cause undesirable interactions between the metals used to make the wire bonds and the traces. Wire-bonding and tape bonding to bond pads having aluminum, copper and gold metallurgies are established processes. Flip-chip interconnection can also be performed directly to bonding pads of a chip using some types of conductive adhesives, especially anisotropic conductive adhesives.

However, when functional or economic reasons make it desirable to perform flip-chip bonding using solder, bond pads of aluminum, copper or gold are unsuitable. As fabricated, most silicon chips are not directly bondable by a fusible conductive material, e.g., a solder, tin, or eutectic composition, among others. The bond pads and wiring traces of silicon chips are typically formed by patterning a doped aluminum layer over ends of substantially pure aluminum or substantially pure copper wiring traces on the front surface of the chip. Aluminum forms a native surface oxide which inhibits wetting by solder and other fusible materials. ‘Wetting’ of one metallic layer by another results in adhesion between the layers by metallurgical bonds.

Although wettable by fusible materials, copper has a higher melting temperature than typical fusible materials and is only somewhat soluble in the fusible material. Thus, UBMs are best formed on copper bond pads prior to applying fusible materials thereto.

On the other hand, microelectronic devices which are fabricated on III-V compound semiconductor wafers, e.g., gallium arsenide (GaAs) for radio frequency use, often include bond pads and wiring traces formed of gold. Gold is different from aluminum and copper in that it is highly soluble in fusible materials such as solder. As the volume of gold contained in the trace is typically small compared to the size of a solder mass, there is a risk that the gold trace will dissolve on contact with the molten solder and become open-circuited.

In addition, it is undesirable for the fusible material to directly contact aluminum or copper wiring traces. Brittle, less conductive intermetallic regions can occur at the interface between the fusible material and the aluminum or copper wiring trace, potentially causing cracks, causing high contact resistance and potentially causing an open-circuit. For these reasons, aluminum, copper or gold bond pads are typically coated with a bondable metal layer or stack of metal layers prior to forming a fusible feature such as a solder bump on the bond pad. The bondable metal layer is generally referred to as an “under bump metallization” (UBM). Despite its apparent specificity, the term UBM has been used to refer to any coating or pre-treatment which is formed to contact another conductive feature, the coating being wettable and bondable by a fusible conductive material, whether or not it is intended for joining a “bump”, e.g., a solder bump, thereto. UBMs typically include a stack of two, three or more than three metal layers, as formed in order from lowest layer contacting the bond pad to highest layer exposed at the surface. The lowest layer includes a metal which is selected for its properties as an “adhesion” layer to adhere strongly to the material underlying the layer, i.e., the aluminum, copper or gold bond pad. A middle layer is selected for its properties as a “barrier” layer, for preventing material from flowing or diffusing past the barrier layer. Sometimes the adhesion layer and the barrier layer are combined. The highest layer of the stack is generally selected for its wettability by the fusible conductive material, and for properties in resisting corrosion. Common examples of the metal layer stacks used as UBMs include, as listed in order from lowest layer to highest: titanium (Ti)/ platinum(Pt) /gold(Au); chromium(Cr)/ copper(Cu)/ silver(Ag); zinc(Zn)/ nickel(Ni)/ gold(Au); and titanium (Ti)/ titanium tungsten oxy-nitride (TiW(ON))/ titanium (Ti)/ gold (Au).

An example of a commonly used technique for applying a solder bump to a microelectronic element such as a chip 10 is illustrated in FIG. 1. While the description below refers to the processing of a “chip”, portions or all of such processing are commonly performed on a wafer-scale as to a wafer containing a plurality of chips. As shown therein, the chip 10 has a major surface 12 and a conductive trace 14 which extends along the major surface. A bond pad 16 is provided of a metal which is not directly bondable by a fusible conductive material. As shown in FIG. 1, the bond pad 16 is provided by a layer of metal disposed over the wiring trace 14. However, the bond pad 16 and the wiring trace may be patterned together from a single metal layer or, alternatively, from a single stack of metal layers. After these features are formed, a passivation layer 18 is formed over the major surface 12 of the chip and patterned to expose the bond pad 16. The passivation layer typically consists essentially of a dielectric material such as an oxide, e.g., glass, or a polymer which can be flowed onto the major surface of the chip and which is preferably self-planarizing.

Subsequently, as shown in FIG. 2, a UBM 20, such as one of those described above, is formed to overlie the bond pad 16. Typically, the UBM 20 is applied by vapor phase deposition through a contact mask. Once the UBM has been applied, a solder bump 22 is formed in contact with the UBM by a technique such as is well known and commonly understood.

While processing as described above relative to FIGS. 1-2 has been widely adopted, it is unsuitable for some types of chips. Some chips become degraded or inoperative if the above-described processing is applied to them. An optoelectronic chip, for example, contains one or more devices exposed at a face of the chip for emitting and/or detecting radiation, e.g., light. Any coating or contamination of the face potentially affects the operational performance of the optoelectronic device. Optoelectronic chips used for imaging purposes require that the optical path not be undesirably affected by intermediate coatings. Chips which contain MEMs devices have delicate structures. Chips which have surface acoustic wave (SAW) devices require the conductive patterns of the chip to remain in pristine condition and directly exposed to a gaseous medium during operation.

This, therefore, presents a conflicting set of requirements, in that the chip can only be prepared for solder bonding by forming a UBM, but these types of chips do not allow the wafer to be processed further after the bond pads are formed.

### SUMMARY OF THE INVENTION

Therefore, according to an aspect of the invention, an article is provided which includes a structure overlying a face of an element. The structure includes a first metal layer and a wettable metal layer overlying the first metal layer. A conductive trace overlies and contacts at least one of the first metal layer and the wettable metal layer, the trace having a composition different from at least one of the first metal layer and the wettable metal layer.

According to another aspect of the invention, a method of fabricating an article is provided which includes forming a structure including a wettable metal layer overlying a face of an element. Thereafter, a conductive trace is formed in contact with the structure.

### BRIEF DESCRIPTION OF THE DRAWINGS

FIGS. 1 and 2 are sectional views illustrating stages in formation of a bump structure on a chip, according to the prior art.

FIGS. 3 and 4 are a plan view and a corresponding sectional view of a chip having a structure which includes a wettable metal layer and a conductive wiring trace overlying the wettable metal layer, according to one embodiment of the invention.

FIGS. 5 and 6 are a plan view and corresponding sectional view of a chip having a structure which includes a wettable metal layer and a conductive wiring trace overlying the structure, according to another embodiment of the invention.

FIG. 7 is a plan view illustrating a microelectronic element according to an embodiment of the invention.

FIGS. 8 through 10 are sectional views illustrating stages in fabricating a capped chip having a structure which includes a wettable metal layer and a conductive wiring trace overlying the structure, according to one embodiment of the invention.

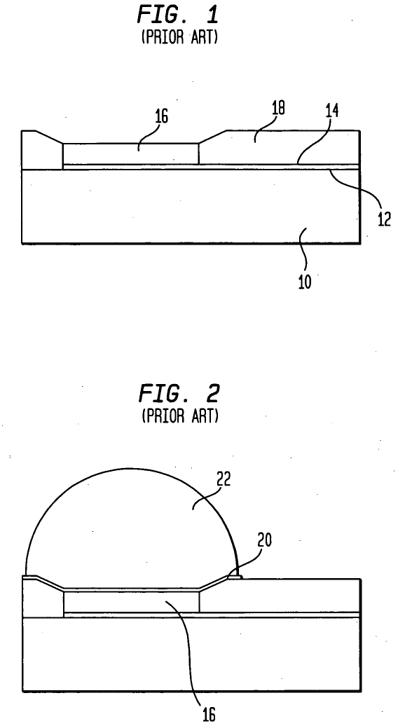

### DETAILED DESCRIPTION

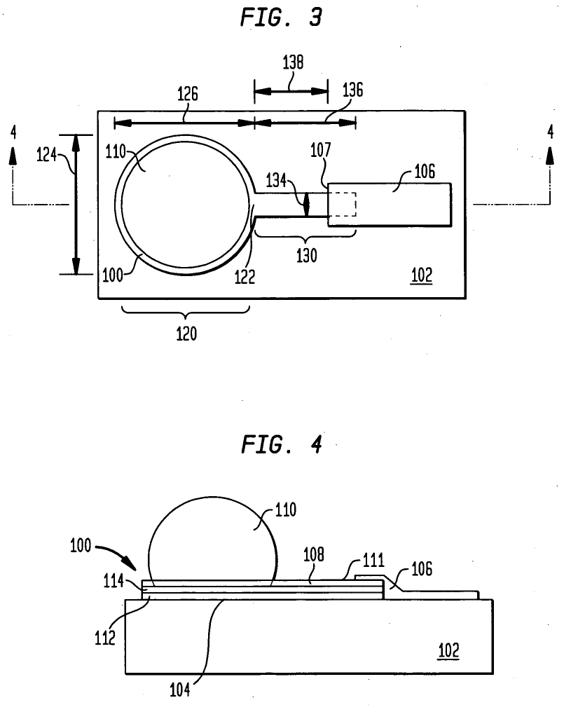

The embodiments of the invention will now be described with reference to FIGS. 3 through 10. In the embodiments of the invention described herein, surface patterns of a device and conductive traces which interconnect the surface patterns to a bond layer of a structure are formed after the bond layer. In such manner, the above-described concerns for avoiding unintentional change in the characteristics of the device, and avoiding damage to elements at the surface of the chip are relieved. In addition, the processes described herein for forming conductive traces after the bond layer result in unique structures.

FIG. 3 is a plan view illustrating a processed chip according to a first embodiment of the invention. FIG. 4 is a sectional view through lines 4-4 of FIG. 3. As shown in FIGS. 3 and 4, a structure 100 having a wettable layer 108 overlies a major surface 104 of a chip 102. As defined herein, a “wettable metal layer” is a layer of metal which tends to cause a fusible conductive material to spread on contact with the layer. Examples of metals included in the wettable metal layer are gold, silver, and tin among others. Such metals are typically soluble in a fusible conductive material such as a solder, tin, lead or eutectic composition. Upon contact with such fusible materials when molten, these metals diffuse into the fusible material to form an alloy. In many cases, the diffusion of the metal from the wettable metal layer into the fusible conductive material produces a composition having a lower melting point than either the wettable metal layer or the fusible conductive material. In such case, the resulting composition spreads laterally to cover the interfacial surface between the fusible material and the wettable metal layer. In such case, the maximum spreading of the resulting composition is primarily limited by surface tension of the mass of fusible material which tends to agglomerate in one mass overlying the wettable metal layer.

Hereinafter, structure 100 will be referred to as a “UBM”, in accordance with the definition given to that term above, and in recognition that the structure need not be used only as an underlying structure for the application of a bump of fusible material. The chip 102 may include, for example, any one of many different types of active or passive electronic or electrical devices such as logic circuits, memory circuits, radio frequency circuits, filters, e.g., SAW devices, passive components such as resistors, capacitors and inductors, power circuits, and optoelectronic devices, among others. Alternatively, or in addition thereto, the chip may contain MEMs devices.

A conductive trace 106 overlies and contacts the UBM 100 to form an electrical connection thereto. The conductive trace 106 conductively connects one or more of the above-described devices of the chip 102 to the UBM 100. The composition of the conductive trace is desirably the same as that normally used to provide conductive traces on the chip 102, according to the type of device it contains, as indicated above. For example, surface acoustic wave (SAW) chips typically have a SAW device structure which includes an aluminum pattern exposed at the major surface 104 of the chip. The aluminum pattern of the SAW device structure is typically formed on a piezoelectric element such as a substrate of lithium tantalate or a region of lithium tantalate material disposed on a semiconductor substrate. The conductive traces 106 of the SAW devices are typically included as part of the aluminum pattern which also defines the SAW device patterns. Most desirably, the SAW device pattern and the conductive traces of the SAW chip are formed simultaneously. In another example, chips such as radio frequency chips that normally include conductive traces of gold, have gold conductive traces 106. The gold traces of such chips are fabricated during a process used to fabricate one or more devices on the chip, except that the UBM 100 is fabricated prior to the conductive traces being fabricated. Alternatively, the conductive traces 106 may be formed of copper.

A feature 110 including a mass of fusible material, such as a solder bump, is joined to the UBM 100, the feature 110 bonded to the wettable layer 108. As shown in FIG. 4, the UBM 100 includes two additional layers of metal which underlie the wettable metal layer. A lower layer 112 is disposed in contact with a dielectric region at a major surface 104 of the chip. The lower layer 112 functions as an “adhesion layer” 112 to provide strong adhesion between the structure and the major surface 104 of the chip. In one embodiment, the adhesion layer 112 of the UBM includes a bond pad of the chip 102. A barrier layer 114 overlies the adhesion layer 112, and underlies the wettable metal layer 108. The barrier layer 114 functions to inhibit materials such as a metal or contaminants from passing or diffusing through the barrier layer to alter the wettable metal layer or other structures formed above the adhesion layer. The barrier layer also inhibits materials from passing or diffusing to alter the adhesion layer or structures which underlie the adhesion layer.

The adhesion layer desirably consists essentially of one or more metals such as aluminum, titanium, chromium, and zinc, which are known for their properties in adhering strongly to the surface of a dielectric layer.

The barrier layer can include a metal such as platinum, copper, nickel, titanium alloy, or conductive nitride of titanium, conductive nitride of tungsten, or conductive nitride of a combination of titanium and tungsten.

The wettable metal layer desirably includes one or more of the following metals, among other possible choices: gold, silver and tin. As particularly shown in FIG. 4, the UBM 100 is a stack of metal layers in which the wettable metal layer 108 is exposed at the top surface 111 of the UBM 100. Referring to FIG. 3, the stack of metal layers of the UBM 100 includes a pad region 120 and a tongue region 130. The geometry of the pad region and the tongue region are such that a fusible conductive material wets the pad region, spreading on contact therewith to cover substantially the entire surface of the pad region. On the other hand, a mass of fusible conductive material sized to cover the pad region 120 does not spread over the entire surface of the tongue region 130.

The reason for the mass of fusible conductive material not spreading onto the surface of the tongue region 130 is the effect of surface tension acting upon the mass, in view of the substantial difference between the width 124 of the pad region 120 and the width 134 of the tongue region 130 at the location 122 where the two regions meet. The pad region 120 also has length 126 in a lengthwise direction of the chip 102 transverse to the direction of the width 124, and the tongue region 130 has length 136 in the lengthwise direction of the chip 102.

Briefly stated, the surface tension acting upon the mass 110 of material on the pad region, which has relatively large width 120, inhibits the mass from spreading onto the tongue region, which has width 134 much smaller than the mass. For this embodiment, the width 134 of the tongue region must be significantly smaller than width 124 of the pad region 110. However, such difference in width is difficult to quantify, because of the different compositions which can be used to make up the wettable metal layer and the fusible conductive material, and the different conditions under which the fusible material can be deposited onto the wettable meal layer.

The tongue needs to be sufficiently narrow to prevent capillary forces from causing the fusible material to flow from the pad region to the location of the edge 107 of the conductive trace 106. Such flow is inhibited when the solder has high surface tension, tending to form a ball-like droplet, and low internal pressure. These conditions lend a large radius to the droplet when viewed in plan, but also low height when viewed in section. A long and narrow tongue also tends to impede the flow of the solder. Under these conditions, the solder hardly flows over the tongue region and becomes increasingly alloyed with the wettable metal. Eventually, the solder reaches a point between the edge 122 of the pad region and the edge 107 of the conductive trace 106 at which the solder becomes so alloyed with the wettable metal that the melting point of the alloyed mixture increases, causing the alloyed mixture to solidify. At that time, the flow of the solder along the tongue region is blocked by the solidified alloy.

Desirably, the dimensions of the tongue are selected in accordance with the amount of time that is provided for the solder to remain molten during the bonding process. The extent that the molten solder spreads along the tongue region is dependent upon the duration of the bonding process. Thus, when all other factors are equal, the tongue region can be shorter when a relatively fast thermal cycle is used. Conversely, a longer tongue region is required when the thermal cycle is relatively slow.

The wettable metal layer should generally include a metal that is not included in the barrier layer which underlies it. For example, the wettable metal layer may include gold, silver, tin, or other wettable metal which diffuses readily into a fusible conductive material. However, the barrier layer must remain to resist diffusion. Therefore, the barrier layer typically includes a metal different from that of the wettable metal layer 108.

As mentioned above, in one embodiment, processing is conducted in an order to form the UBM 100, followed by at least some processing to complete one of the above-mentioned devices on a substrate and conductive traces leading thereto. In one embodiment, a device is first formed on a substrate, followed by formation of the UBM 100. Thereafter, the conductive traces are formed on the surface of the chip which conductively connect the UBM 100 to elements of the device provided in the chip. In either of the embodiments, the adhesion layer of the UBM can include an element of a metal pattern of the chip, as formed prior to the UBM, and prior to forming the final conductive traces of the chip.

In addition, there need not be separate barrier and adhesion layers in every instance. Instead, by appropriate choice of the material such as titanium, the adhesion layer can function as the barrier layer.

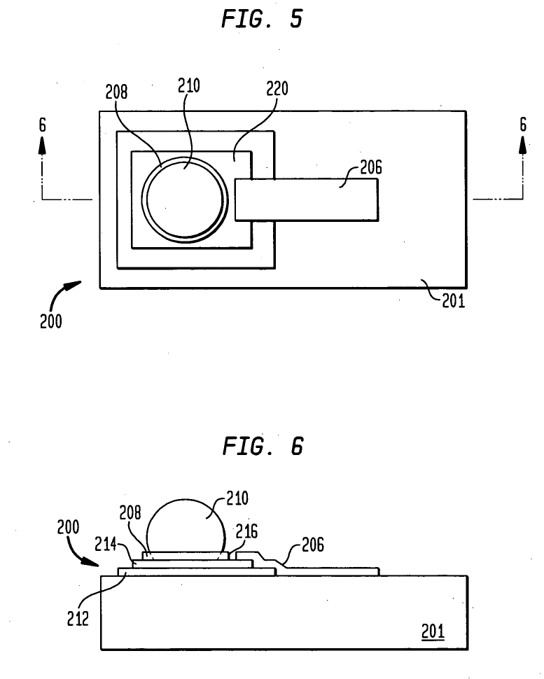

Another embodiment of the invention is illustrated in plan view in FIG. 5, and in a corresponding sectional view in FIG.6, the section taken through lines 6-6 of FIG. 5. As shown therein, in this embodiment, a structure 200 is formed on a chip 201 in such way that a wettable metal layer 208 thereof overlies only a portion of the underlying structure including the barrier layer 214 and the adhesion layer 212. In this embodiment, trace 206 conductively and directly contacts at least one of the barrier layer 214 and the adhesion layer 212, but not the wettable metal layer 208. In the particular example shown, the structure 200 is nested, such that the adhesion layer 212 is larger than the barrier layer 214, and the barrier layer is larger, in turn, than the wettable metal layer 208. Similar to that described above, the wettable metal layer 208 includes a metal such as described above which facilitates the spreading of a fusible conductive material along its surface to form a bump 210, for example. The wettable metal layer 208 includes a metal which is not included in the barrier layer 214 which underlies it. In addition, the barrier layer 214 is such that it is either not wettable by the fusible conductive material, or it retards a flow of the fusible material along its surface. This characteristic and the fact that the trace 206 does not contact the wettable metal layer reduces or eliminates the possibility that the fusible material spreads beyond the wettable metal layer 208 to contact the conductive trace 206.

This arrangement is particularly advantageous with regard to chips in which the conductive traces are formed of metals such as gold, for example, which are wettable, and may be soluble in the fusible conductive material. Inhibiting or preventing contact with the traces reduces the likelihood of damage to or even open-circuiting of such conductive traces.

In a particular embodiment, the wettable metal layer 208 includes a metal such as gold, silver, or tin, which forms an alloy with the fusible material, e.g., solder, the alloy having a lower melting point than the melting point of either the original metal or the solder. The reduction in the melting point is the impetus that causes the fusible material to spread along the surface of the wettable layer 208. As all metals are intersoluble, all molten metals can wet higher melting point metals. However, not all molten metals are capable of spreading over a layer of a higher melting point metal. As one example, molten tin wets a layer of gold and readily spreads over the surface of such layer because gold-tin alloys have a melting point which is 15° C. lower than that of pure tin. Molten tin also wets platinum, but does not spread over a platinum layer because platinum-tin alloys have melting points above that of pure tin.

The particular combination of the wettable metal and fusible material determines the extent to which the fusible material spreads over the surface of the wettable metal layer 208. The wettable metal dissolves into the fusible material until the barrier layer 214 is reached, as shown by the extension of the bump 210 into the wettable metal layer 208. In one embodiment, the portion 220 of the structure 200 not covered by the wettable metal layer 208 is itself not wettable by the fusible conductive material. In one example of such embodiment, the uncovered portion 220 of the structure 200 is a metal such as aluminum. In a particular embodiment, the uncovered portion 220 defines a bond pad which consists essentially of aluminum and the conductive trace 206 consists essentially of aluminum. A key difference from conventional structures and processes is that the aluminum wiring trace 206 overlies the bond pad 220 to contact a top surface of the bond pad. As in the above-described embodiment, such structure results from the aluminum trace 206 being formed after the wettable metal layer 208.

In another embodiment, the composition of the barrier layer 214 is preferably selected such that the material of the barrier layer dissolves into the fusible material to raise the melting point of the resulting alloy. As a result of these differences in composition, the fusible material spreads over the wettable metal layer 208 but does not spread much beyond the edge 216 of that layer 208, if at all.

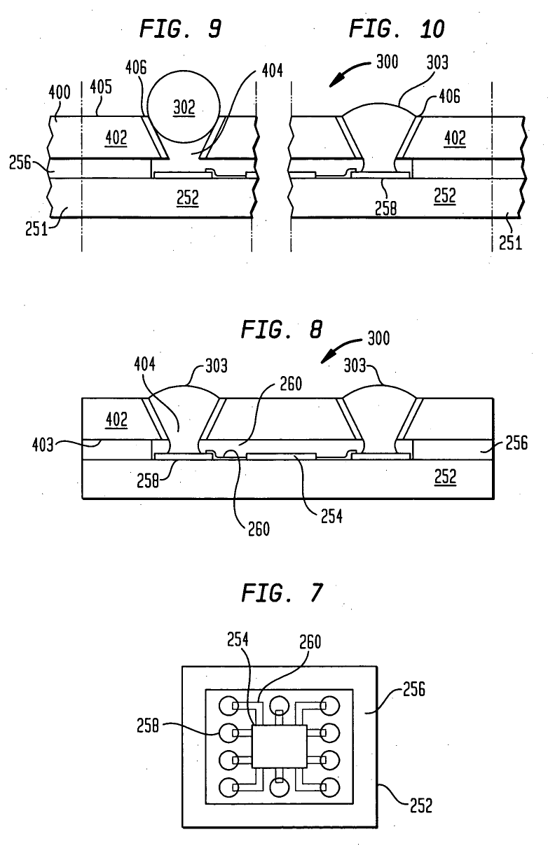

FIGS. 7-10 illustrate an embodiment in which a processed chip 252 formed according to one of the above-described embodiments, is assembled to a cap 402 (FIG. 8) having through holes 404 in registration with bondable structures 258 of the chip, the bondable structures being such as the structures 100 and 200 described above with reference to FIGS. 3-4, or with reference to FIGS. 5-6, respectively. The assembling process results in a capped chip having conductive interconnects extending into the through holes. Such capped chip and processes for fabricating it are described in U.S. Patent Application No. Not Yet Assigned, Filed Sep. 24, 2004, entitled “Structure And Method Of Making Capped Chips Having Vertical Interconnects,” which names Giles Humpston, David B. Tuckerman, Bruce M. McWilliams, Belgacem Haba, and Craig S. Mitchell as inventors. This application is hereby incorporated by reference herein.

In such embodiment, the chip (FIG. 7) can have a device 254 such as one of those described above with reference to FIGS. 3-4, such device requiring a cap in order to operate or function most reliably. The bondable structures 258 are formed before further processing the chip 252 to form traces 260 which interconnect the structures 258 to the device 254.

A sealing material 256 is disposed on the chip, in the shape of a “picture frame”, to surround the bondable structures, traces and device. The preceding steps are desirably performed while the chip 252 remains attached to other like chips 252 in form of a wafer 251 (FIG. 9). Thereafter, a cap wafer 400 including caps 402 corresponding to each of the chips 252 is bonded to the chips by way of the sealing material 256.

Subsequently, steps are performed to fabricate conductive interconnects including a fusible material which extend from the bondable structures 258 through the through holes 404 in the cap wafer 400. In a particular process shown in FIG. 9, a solder ball 302 is provided at a top surface 405 of the cap wafer, and allowed to rest inside the through hole 404, which is tapered. A UBM 406 is provided on a sidewall of the through hole 404.

Thereafter, as shown in FIG. 10, the assembled structure including the wafer 251, cap wafer 400 and the solder ball 302 is heated, such that the solder ball melts and fuses to the UBM 406 and flows onto and wets the bondable structure 258 to form a metallurgical bond thereto. At the conclusion of this processing, a conductive interconnect 303 is formed which extends from the bondable structure 258 at least partially through the through hole 404.

Subsequently, the joined assembly of the wafer and the cap wafer is severed to provide individual capped chips, i.e., capped chip 300 (FIG. 8). Such capped chip includes a cavity 260 which fully encloses the device 254. In a particular embodiment, by judiciously selecting the sealing material 256 and the process used to form the interconnect 303, the capped chip 300 encloses the device 254 in a way that hermetically seals the device, such as in the case of a SAW device.

The embodiments of the invention described above include a bondable structure provided on a face of a chip. However, in other embodiments, a bondable structure is provided other types of electronic elements. In one such embodiment, a bondable structure, as described above with reference to either FIGS. 3-4 or FIGS. 5-6 is provided on a microelectronic substrate, such as, illustratively, a glass, ceramic, or semiconductor material substrate. In such embodiment, the microelectronic substrate has a contact which includes at least a portion of the structure. In another embodiment, a bondable structure as described above with reference to either FIGS. 3-4 or FIGS. 5-6 is provided on a circuit panel, being either a rigid, semi-rigid or flexible circuit panel. In such embodiment, the circuit panel has a terminal which includes at least a portion of the structure.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. An article, comprising:
an element having a face;
a structure overlying said face, said structure including a first metal layer and a wettable metal layer overlying said first metal layer; and
a conductive trace overlying and contacting at least one of said first metal layer and said wettable metal layer, said trace having a composition different from at least one of said first metal layer and said wettable metal layer.

2. The article as claimed in claim 1, wherein said wettable metal layer overlies only a portion of said first layer, said conductive trace overlying said first layer but not said wettable metal layer.

3. The article as claimed in claim 2, wherein said conductive trace does not contact said wettable metal layer.

4. The article as claimed in claim 3, wherein said composition of said conductive trace is the same as a composition of said wettable metal layer.

5. The article as claimed in claim 2, wherein said first metal layer includes a portion disposed between an edge of said wettable metal layer and an edge of said conductive trace, said portion adapted to remain substantially unwetted by a fusible conductive material which wets said wettable metal layer.

6. The article as claimed in claim 2, wherein said first metal layer includes a portion disposed between an edge of said wettable metal layer and an edge of said conductive trace, said portion being adapted to retard a flow of a fusible conductive material which wets said wettable metal layer.

7. The article as claimed in claim 3, wherein said first metal layer includes an adhesion layer contacting said element and a barrier layer overlying said adhesion layer, said wettable metal layer overlying said barrier layer, and said conductive trace overlying said barrier layer.

8. The article as claimed in claim 7, wherein said barrier layer overlies only a portion of said adhesion layer.

9. The article as claimed in claim 1, wherein said element includes a microelectronic substrate having a contact, said contact including at least a portion of said structure.

10. The article as claimed in claim 1, wherein said element includes a semiconductor chip having a bond pad, said bond pad including at least a portion of said structure.

11. The article as claimed in claim 1, wherein said element includes a circuit panel having a terminal, said terminal including said structure.

12. The article as claimed in claim 1, wherein said wettable metal layer includes a pad region and a tongue region extending laterally from said pad region along said face, said conductive trace overlying and contacting said tongue region, said pad region and said tongue region each having length and width in directions running parallel to said face, said tongue region having width much smaller than a width of said pad region, such that said tongue region is adapted to remain substantially unwetted by a fusible conductive material which wets said pad region.

13. The article as claimed in claim 1, wherein said element includes a surface acoustic wave (SAW) device, said SAW device including a patterned metal layer including said conductive trace.

14. The article as claimed in claim 13, wherein said SAW device includes a piezoelectric device region consisting essentially of lithium tantalate, and said patterned metal layer is disposed on said device region, said patterned metal layer consisting essentially of aluminum.

15. The article as claimed in claim 1, wherein said element includes at least one of an optoelectronic device and a MEMs device.

16. The article as claimed in claim 1, wherein said conductive trace is not wettable by a fusible conductive material for which said wettable metal layer is wettable.

17. The article as claimed in claim 1, wherein said conductive trace consists essentially of a metal selected from the group consisting of aluminum, copper and gold.

18. The article as claimed in claim 1, wherein said wettable metal layer consists essentially of a metal selected from the group consisting of gold and silver.

19. The article as claimed in claim 18, wherein said barrier layer consists essentially of a metal selected from the group consisting of titanium, platinum, chromium, and nickel.

20. The article as claimed in claim 19, wherein said adhesion layer consists essentially of a metal selected titanium, chromium, and zinc.

21. A capped chip including the article as claimed in claim 1, further comprising:
a cap member having a top surface, a bottom surface opposite said top surface, and at least one through hole extending between said top and bottom surfaces, said cap member mounted to overlie said front surface of said chip; and
an electrically conductive interconnect extending from said bond pad at least partially through said through hole.

22. A method of fabricating an article, comprising:
forming a structure including a wettable metal layer overlying a face of an element; and
thereafter forming a conductive trace in contact with said structure.

23. The method as claimed in claim 22, wherein said conductive trace has a composition different from said wettable metal layer.

24. The method as claimed in claim 22, wherein said element includes a circuit panel.

25. The method as claimed in claim 22, wherein said element includes a microelectronic substrate.

26. The method as claimed in claim 22, wherein said element includes a semiconductor chip.

27. The method as claimed in claim 22, wherein said element includes a dielectric layer, and said step of forming said conductive trace includes forming a patterned metal layer overlying said dielectric layer.

28. The method as claimed in claim 22, further comprising bonding a mass of a fusible conductive material to said wettable metal layer, said mass not contacting said conductive trace.

29. The method as claimed in claim 28, wherein said step of bonding forms a bump of said fusible conductive material.

30. The method as claimed in claim 28, wherein said element is a semiconductor chip, said method further comprising mounting a cap to overlie said face of said chip, said cap having a through hole in registration with said wettable metal region, said step of bonding being performed after said step of mounting.

31. The method as claimed in claim 30, wherein said cap has an inner surface facing said chip and an outer surface opposite said inner surface, wherein said mass is formed by providing a quantity of said fusible conductive material at said outer surface and causing said fusible conductive material to flow through said through hole to wet said wettable metal layer.

32. The method as claimed in claim 31, wherein said quantity of fusible conductive material includes a solder ball.

33. The method as claimed in claim 22, further comprising flowing a fusible conductive material onto said wettable metal region, said fusible conductive material prevented from contacting said conductive trace by a shape of said wettable metal region.

34. The method as claimed in claim 22, wherein said wettable metal region includes a first metal layer and a second metal layer overlying only a portion of said first metal layer, said conductive trace overlying said first metal layer but not said second metal layer, said method further comprising flowing said fusible conductive material onto said second metal layer, said first metal layer forming a first alloy with said fusible conductive material, said first alloy having a higher melting point than a melting point of said fusible conductive material, such that said fusible conductive material is prevented from contacting said conductive trace.

35. The method as claimed in claim 34, wherein said first layer includes an adhesion layer contacting said element and a barrier layer overlying said adhesion layer, said second layer overlying at least a portion of said barrier layer.

36. The method as claimed in claim 34, wherein said conductive trace includes aluminum.

37. The method as claimed in claim 36, wherein said step of forming a conductive trace includes forming a patterned metal layer including a component of a surface acoustic wave device and said conductive trace.

38. The method as claimed in claim 22, further comprising flowing a fusible conductive material onto said wettable metal region, wherein said fusible conductive material is prevented from spreading onto said conductive trace by a shape of said wettable metal region.

39. The method as claimed in claim 34, wherein said second metal layer forms a second alloy with the fusible conductive material, said second alloy having a lower melting point than said fusible conductive material, such that said fusible conductive material spreads on contact with said second metal layer.

40. The method as claimed in claim 39, wherein said fusible conductive material is prevented from spreading vertically through said first layer by said first alloy formed with said first layer.
